(19) United States
(12) Patent Application Publication
(10) Pub. No.: US 2016/0352266 A1
(43) Pub. Date: Dec. 1, 2016

(54) MAGNETIC SENSOR INTEGRATED CIRCUIT, MOTOR ASSEMBLY AND APPLICATION DEVICE

(71) Applicant: Johnson Electric S.A., Murten (CH)

(72) Inventors: Chi Ping SUN, Hong Kong (CN); Fei XIN, Shen Zhen (CN); Ken WONG, Hong Kong (CN); Shing Hin YEUNG, Hong Kong (CN); Shu Juan HUANG, Shen Zhen (CN); Yun Long JIANG, Shen Zhen (CN); Yue LI, Hong Kong (CN); Bao Ting LIU, Shen Zhen (CN); En Hui WANG, Shen Zhen (CN); Xiu Wen YANG, Shen Zhen (CN); Li Sheng LIU, Shen Zhen (CN); Yan Yun CUI, Shen Zhen (CN)

(21) Appl. No.: 15/231,283

(22) Filed: Aug. 8, 2016

Related U.S. Application Data
(63) Continuation-in-part of application No. 14/822,353, filed on Aug. 10, 2015.
Application No. 14/822,353 is a continuation of application No. PCT/CN2015/086422, filed on Aug. 7, 2015.

(30) Foreign Application Priority Data
Aug. 8, 2014 (CN) 201410390592.2
Aug. 15, 2014 (CN) 201410404474.2
Apr. 1, 2016 (CN) 201610204132.5
Jun. 2, 2016 (CN) 201610392349.3

(51) Int. Cl. H02P 6/16; H02K 11/215; G01R 33/07; H02P 6/20

(52) U.S. Cl. CPC H02P 6/16; H02P 6/20; H02K 11/215; G01R 33/072

(57) ABSTRACT

A magnetic sensor integrated circuit includes an electronic circuit arranged on a semiconductor substrate, and input ports and first and second output ports extending out from a housing. The electronic circuit includes a magnetic field detection circuit and an output control circuit. The magnetic field detection circuit is configured to detect an external magnetic field and generate magnetic field detection information. The first output port outputs the magnetic field detection information to an outside of the housing. The output control circuit is configured to control, based at least on the magnetic field detection information, the integrated circuit to operate in at least one of a first state in which a current flows from the second output port to an outside of the integrated circuit and a second state in which a current flows from the outside of the integrated circuit to the second output port.

### CROSS REFERENCE TO RELATED APPLICATIONS

This non-provisional patent application is a continuation-in-part of U.S. patent application Ser. No. 14/822,353, which claims priority to Chinese Patent Application No. 201410390592.2, filed on Aug. 8, 2014 and to Chinese Patent Application No. 201410404474.2, filed on Aug. 15, 2014. In addition, this non-provisional patent application claims priority under the Paris Convention to PCT Patent Application No. PCT/CN2015/086422, filed with the Chinese Patent Office on Aug. 7, 2015, to Chinese Patent Application No. CN201610204132.5, filed with the Chinese Patent Office on Apr. 1, 2016, and to Chinese Patent Application No. CN201610392349.3 filed with the Chinese Patent Office on Jun. 2, 2016, all of which are incorporated herein by reference in their entirety.

### FIELD

The disclosure relates to magnetic field detection technology.

### BACKGROUND

During starting of a synchronous motor, the stator produces an alternating magnetic field causing the permanent magnetic rotor to be oscillated. The amplitude of the oscillation of the rotor increases until the rotor begins to rotate, and finally the rotor is accelerated to rotate in synchronism with the alternating magnetic field of the stator. To ensure the starting of a conventional synchronous motor, a starting point of the motor is set to be low, which results in that the motor cannot operate at a relatively high working point, thus the efficiency is low. In another aspect, the rotor cannot be ensured to rotate in a same direction every time since a stop or stationary position of the permanent magnetic rotor is not fixed. Accordingly, in applications such as a fan and water pump, the impeller driven by the rotor has straight radial vanes, which results in a low operational efficiency of the fan and water pump.

FIG. 1 illustrates a conventional drive circuit for a synchronous motor, which allows a rotor to rotate in a same predetermined direction in every time it starts. In the circuit, a stator winding 1 of the motor is connected in series with a TRIAC between two terminals M and N of an AC power source VM, and an AC power source VM is converted by a conversion circuit DC into a direct current voltage and the direct current is supplied to a position sensor H. A magnetic pole position of a rotor in the motor is detected by the position sensor H, and an output signal Vh of the position sensor H is connected to a switch control circuit PC to control the bidirectional thyristor T.

FIG. 2 illustrates a waveform of the drive circuit. It can be seen from FIG. 2 that, in the drive circuit, no matter the bidirectional thyristor T is switched on or off, the AC power source supplies power for the conversion circuit DC so that the conversion circuit DC constantly outputs and supplies power for the position sensor H (referring to a signal VH in FIG. 2). In a low-power application, in a case that the AC power source is commercial electricity of about 200V, the electric energy consumed by two resistors R2 and R3 in the conversion circuit DC is more than the electric energy consumed by the motor.

The magnetic sensor applies Hall effect, in which, when current I runs through a substance and a magnetic field B is applied in a positive angle with respect to the current I, a potential difference V is generated in a direction perpendicular to the direction of current I and the direction of the magnetic field B. The magnetic sensor is often implemented to detect the magnetic polarity of an electric rotor.

As the circuit design and signal processing technology advances, there is a need to improve the magnetic sensor integrated circuit for the ease of use and accurate detection.

### SUMMARY

In an aspect, a magnetic sensor integrated circuit is provided according to an embodiment of the disclosure. The magnetic sensor integrated circuit includes a housing, a semiconductor substrate arranged in the housing, an electronic circuit arranged on the semiconductor substrate, and input ports, a first output port and a second output port extending out from the housing, where the electronic circuit includes:

a magnetic field detection circuit configured to detect an external magnetic field and generate magnetic field detection information, where the first output port is connected to the magnetic field detection circuit for outputting the magnetic field detection information to an outside of the housing; and

an output control circuit configured to control, based at least on the magnetic field detection information, the integrated circuit to operate in at least one of a first state in which a current flows from the second output port to an outside of the integrated circuit and a second state in which a current flows from the outside of the integrated circuit to the second output port.

Preferably, the magnetic field detection circuit may include:

a magnetic field detection element configured to detect the external magnetic field and generate an electrical signal;

a signal processing unit configured to amplify and descramble the electrical signal; and

a conversion unit configured to convert the amplified and descrambled electrical signal into the magnetic field detection information, where an output terminal of the conversion unit is connected to the output control circuit and the first output port.

Preferably, the magnetic field detection information may be a switch-type digital signal.

Preferably, the integrated circuit may include at least four ports extending out from the housing.

Preferably, the integrated circuit may exactly include four ports extending out from the housing.

Preferably, the input ports may include an input port configured to connect an external alternating current (AC) power supply, and the output control circuit may be configured to control, based on a polarity of the AC power supply and the magnetic field detection information, the integrated circuit to switch between at least the first state and the second state.

Preferably, the output control circuit may include a first switch and a second switch, the first switch and the second output port may be connected in a first current path, the second switch and the second output port may be connected in a second current path having a direction opposite to that of the first current path, and the first switch and the second switch may be turned on selectively based on the magnetic field detection information.

Preferably, the output control circuit may include a first current path in which a current flows out from the second output port, a second current path in which a current flows in from the second output port and a switch connected in one of the first current path and the second current path, where the switch may be configured to control, based on the magnetic field detection information outputted from the magnetic field detection circuit, the first current path and the second current path to be turned on selectively.

Preferably, the output control circuit may be configured to control a load current to flow through the second output port in a case that the AC power supply is in a positive half cycle and the external magnetic field is a first polarity or in a case that the AC power supply is in a negative half cycle and the external magnetic field is a second polarity opposite to the first polarity, and control no load current to flow through the second output port in a case that the AC power supply is in a positive half cycle and the external magnetic field is the second polarity or in a case that the AC power supply is in a negative half cycle and the external magnetic field is the first polarity.

Preferably, the input ports may include a first input port and a second input port configured to connect the external AC power supply, and the integrated circuit may further include a rectifying circuit configured to convert an alternating current voltage outputted from the external power supply into a direct current voltage.

Preferably, the integrated circuit may further include a voltage adjusting circuit configured to adjust a first voltage outputted from the rectifying circuit to a second voltage, where the first voltage is a supply voltage of the output control circuit, the second voltage is a supply voltage of the magnetic field detection circuit, and an average of the first voltage is greater than that of the second voltage.

In another aspect, a motor assembly is provided according to an embodiment of the disclosure. The motor assembly includes a motor and a motor drive circuit, where the motor drive circuit includes the magnetic sensor integrated circuit described above.

Preferably, the motor drive circuit may further include a bidirectional switch connected in series with the motor across the external AC power supply, and the second output port of the magnetic sensor integrated circuit may be connected to a control terminal of the bidirectional switch.

Preferably, the motor may include a stator and a permanent rotor, and the stator may include a stator core and a single-phase winding wound on the stator core.

Preferably, the motor assembly may further include a voltage dropper configured to reduce an output voltage of the AC power supply and provide the reduced voltage of the AC power supply to the magnetic sensor integrated circuit.

Preferably, the magnetic sensor integrated circuit may be configured to control the bidirectional switch to be turned on in a case the AC power supply is in a positive half cycle and a magnetic field of the permanent rotor is a first polarity or in a case that the AC power supply is in a negative half cycle and the magnetic field of the permanent rotor is a second polarity opposite to the first polarity, and control the bidirectional switch to be turned off in a case that the AC power supply is in a negative half cycle and a magnetic field of the permanent rotor is the first polarity or in a case that the AC power supply is in a positive half cycle and a magnetic field of the permanent rotor is the second polarity.

Preferably, the magnetic sensor integrated circuit may be configured to control a current to flow from the integrated circuit to the bidirectional switch in a case that a signal outputted from the AC power supply is in a positive half cycle and the magnetic field of the permanent rotor is the first polarity, or control a current to flow from the bidirectional switch to the integrated circuit in a case that the signal outputted from the AC power supply is in a negative half cycle and the magnetic field of the permanent rotor is the second polarity.

In another aspect an application device including the motor assembly is provided according to an embodiment of the disclosure.

Preferably, the application device may be a pump, a fan, a household appliance or a vehicle.

Functions of existing magnetic sensors are extended with the magnetic sensor integrated circuit according to the disclosure. The overall circuit cost is reduced and circuit reliability is improved.

### BRIEF DESCRIPTION OF THE DRAWINGS

The drawings to be used in the descriptions of embodiments or conventional technology are described briefly as follows, so that technical solutions according to the embodiments of the disclosure or according to conventional technology may become clearer. Apparently, the drawings in the following descriptions only illustrate some embodiments of the disclosure. For those ordinary skilled in the art, other drawings may be obtained based on these drawings without any creative work.

FIG. 1 illustrates a prior art drive circuit for a synchronous motor, according to an embodiment of the present disclosure;

FIG. 2 illustrates a waveform of the drive circuit shown in FIG. 1;

FIG. 3 illustrates a diagrammatic representation of a synchronous motor, according to an embodiment of the present disclosure;

FIG. 4 illustrates a block diagram of a drive circuit for a synchronous motor, according to an embodiment of the present disclosure;

FIG. 5 illustrates a drive circuit for a synchronous motor, according to an embodiment of the present disclosure;

FIG. 6 illustrates a waveform of the drive circuit shown in FIG. 5;

FIGS. 7 to 10 illustrate different embodiments of a drive circuit of a synchronous motor, according to an embodiment of the present disclosure;

FIG. 11 is a schematic structural diagram of a magnetic sensor integrated circuit according to an embodiment of the disclosure;

FIG. 12 is a schematic structural diagram of an electronic circuit in a magnetic sensor integrated circuit according to an embodiment of the disclosure;

FIG. 13 is a schematic structural diagram of an output control circuit in a magnetic sensor integrated circuit according to an embodiment of the disclosure;

FIG. 14 is a schematic structural diagram of an output control circuit in a magnetic sensor integrated circuit according to an embodiment of the disclosure;

FIG. 15 is a schematic structural diagram of an output control circuit in a magnetic sensor integrated circuit according to an embodiment of the disclosure;

FIG. 15A is a schematic structural diagram of an output control circuit in a magnetic sensor integrated circuit according to an embodiment of the disclosure;

FIG. 16 is a schematic structural diagram of a magnetic sensor integrated circuit according to an embodiment of the disclosure;

FIG. 17 is a schematic structural diagram of a rectifying circuit in a magnetic sensor integrated circuit according to an embodiment of the disclosure;

FIG. 18 is a diagram of a specific implementation of the rectifying circuit in FIG. 17.

FIG. 19 is a schematic structural diagram of a magnetic field detection circuit in a magnetic sensor integrated circuit according to an embodiment of the disclosure;

FIG. 20 is a schematic structural diagram of a motor assembly according to an embodiment of the disclosure; and

FIG. 21 is a schematic structural diagram of a motor in a motor assembly according to an embodiment of the disclosure.

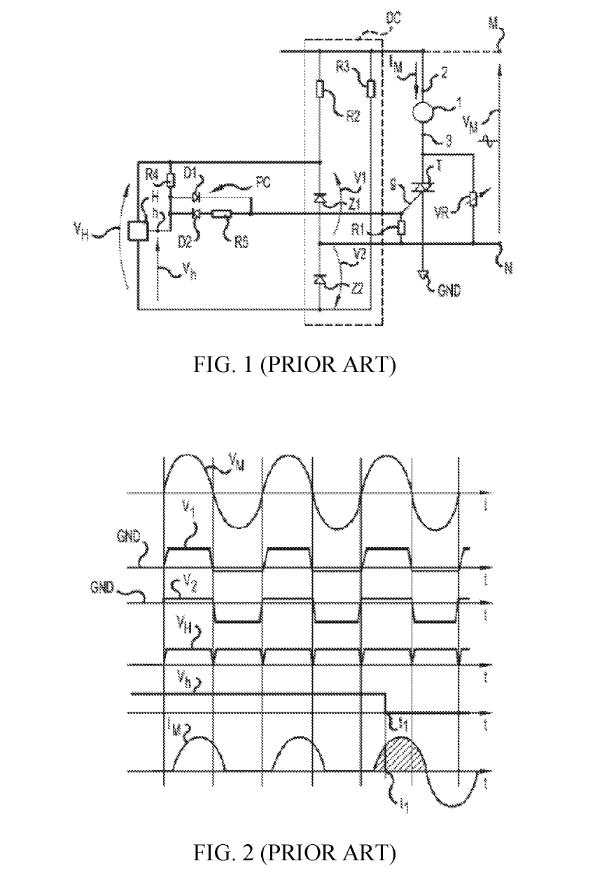

### DETAILED DESCRIPTION

Technical solutions according to embodiments of the disclosure are described clearly and completely in conjunction with the drawings in the embodiments of the disclosure hereinafter. Apparently, the described embodiments are only a few rather than all of the embodiments of the disclosure. Other embodiments obtained by those skilled in the art without any creative work based on the embodiments of the disclosure fall into the scope of protection of the disclosure.

More specific details are set forth in the following descriptions for sufficient understanding of the disclosure, but the disclosure may further be implemented in other ways different from the way described herein. Similar extensions can be made by those skilled in the art without departing from the spirit of the disclosure, and therefore, the disclosure is not limited to particular embodiments disclosed hereinafter.

Hereinafter, a magnetic sensor integrated circuit according to an embodiment of the disclosure is explained by taking the magnetic sensor integrated circuit being applied in a motor as an example.

FIG. 3 schematically shows a synchronous motor according to an embodiment of the present invention. The synchronous motor 810 includes a stator 812 and a permanent magnet rotor 814 rotatably disposed between magnetic poles of the stator 812, and the stator 812 includes a stator core 815 and a stator winding 816 wound on the stator core 815. The rotor 814 includes at least one permanent magnet forming at least one pair of permanent magnetic poles with opposite polarities, and the rotor 814 operates at a constant rotational speed of 60 f/p rpm during a steady state phase in a case that the stator winding 816 is connected to an AC power supply, where f is a frequency of the AC power supply and p is the number of pole pairs of the rotor.

Non-uniform gap 818 is formed between the magnetic poles of the stator 812 and the permanent magnetic poles of the rotor 814 so that a polar axis R of the rotor 814 has an angular offset a relative to a central axis S of the stator 812 in a case that the rotor is at rest. The rotor 814 may be configured to have a fixed starting direction (a clockwise direction in this embodiment as shown by the arrow in FIG. 3) every time the stator winding 816 is energized. The stator and the rotor each have two magnetic poles as shown in FIG. 3. It can be understood that, in other embodiments, the stator and the rotor may also have more magnetic poles, such as 4 or 6 magnetic poles.

A position sensor 820 for detecting the angular position of the rotor is disposed on the stator 812 or at a position near the rotor inside the stator, and the position sensor 820 has an angular offset relative to the central axis S of the stator. Preferably, this angular offset is also a, as in this embodiment. Preferably, the position sensor 820 is a Hall effect sensor.

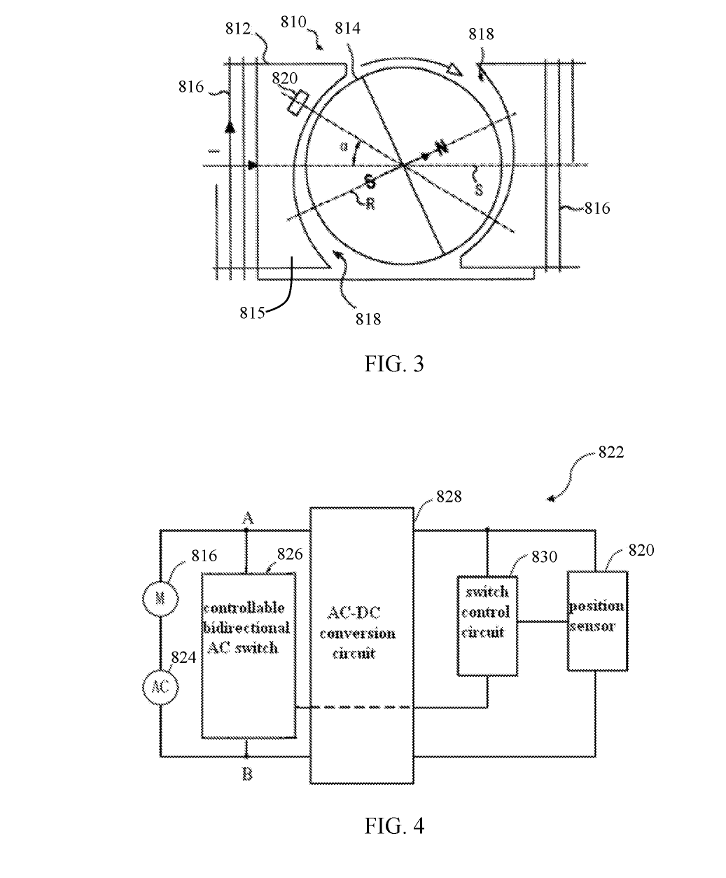

FIG. 4 shows a block diagram of a drive circuit for a synchronous motor according to an embodiment of the present invention. In the drive circuit 822, the stator winding 816 and the AC power supply 824 are connected in series between two nodes A and B. Preferably, the AC power supply 824 may be a commercial AC power supply with a fixed frequency, such as 50 Hz or 60 Hz, and a supply voltage may be, for example, 110V, 220V or 230V. A controllable bidirectional AC switch 826 is connected between the two nodes A and B, in parallel with the stator winding 816 and the AC power supply 824. Preferably, the controllable bidirectional AC switch 826 is a TRIAC, of which two anodes are connected to the two nodes A and B respectively. It can be understood that, the controllable bidirectional AC switch 826 alternatively may be two silicon control rectifiers reversely connected in parallel, and control circuits may be correspondingly configured to control the two silicon control rectifiers in a preset way. An AC-DC conversion circuit 828 is also connected between the two nodes A and B. An AC voltage between the two nodes A and B is converted by the AC-DC conversion circuit 828 into a low voltage DC. The position sensor 820 may be powered by the low voltage DC output by the AC-DC conversion circuit 828, for detecting the magnetic pole position of the permanent magnet rotor 814 of the synchronous motor 810 and outputting a corresponding signal. A switch control circuit 830 is connected to the AC-DC conversion circuit 828, the position sensor 820 and the controllable bidirectional AC switch 826, and is configured to control the controllable bidirectional AC switch 826 to be switched between a switch-on state and a switch-off state in a predetermined way, based on the magnetic pole position of the permanent magnet rotor which is detected by the position sensor and polarity information of the AC power supply 824 which may be obtained from the AC-DC conversion circuit 828, such that the stator winding 816 urges the rotor 814 to rotate only in the above-mentioned fixed starting direction during a starting phase of the motor. According to this embodiment of the present invention, in a case that the controllable bidirectional AC switch 826 is switched on, the two nodes A and B are shorted, the AC-DC conversion circuit 828 does not consume electric energy since there is no current flowing through the AC-DC conversion circuit 828, hence, the utilization efficiency of electric energy can be improved significantly.

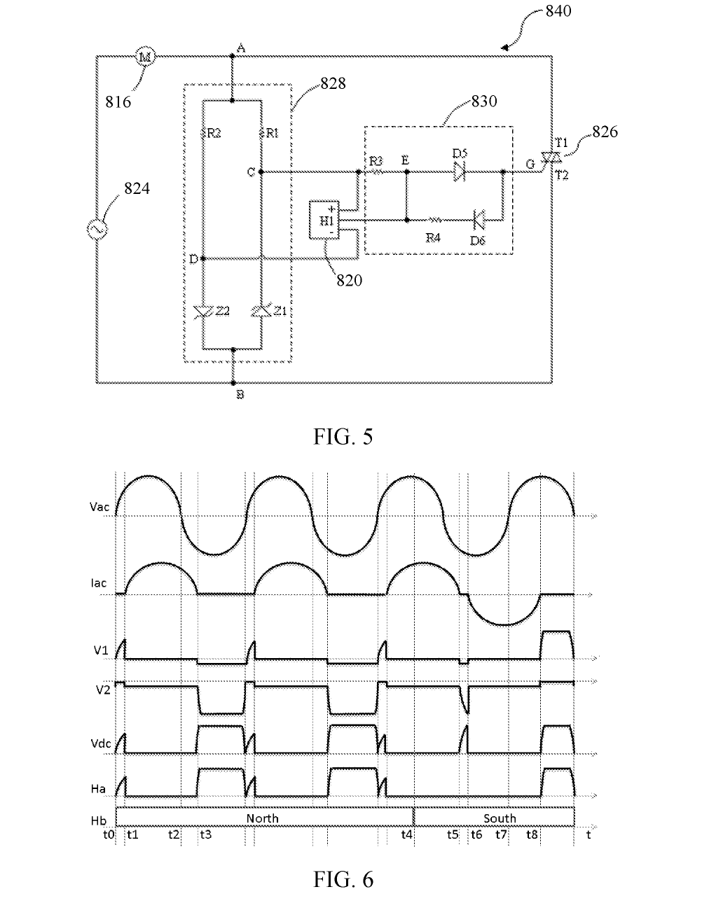

FIG. 5 shows a circuit diagram of a drive circuit 840 for a synchronous motor according to a first embodiment of the present disclosure. The stator winding 816 of the synchronous motor is connected in series with the AC power supply 824 between the two nodes A and B. A first anode T1 of the TRIAC 826 is connected to the node A, and a second anode T2 of the TRIAC 826 is connected to the node B. The AC-DC conversion circuit 828 is connected in parallel with the TRIAC 826 between the two nodes A and B. An AC voltage between the two nodes A and B is converted by the AC-DC conversion circuit 828 into a low voltage DC (preferably, low voltage ranges from 3V to 18V). The AC-DC conversion circuit 828 includes a first zener diode Z1 and a second zener diode Z2 which are reversely connected in parallel between the two nodes A and B via a first resistor R1 and a second resistor R2 respectively. A high voltage output terminal C of the AC-DC conversion circuit 828 is formed at a connection point of the first resistor R1 and a cathode of the first zener diode Z1, and a low voltage output terminal D of the AC-DC conversion circuit 828 is formed at a connection point of the second resistor R2 and an anode of the second zener diode Z2. The voltage output terminal C is connected to a positive power supply terminal of the position sensor 820, and the voltage output terminal D is connected to a negative power supply terminal of the position sensor 820. Three terminals of the switch control circuit 830 are connected to the high voltage output terminal C of the AC-DC conversion circuit 828, an output terminal H1 of the position sensor 820 and a control electrode G of the TRIAC 826 respectively. The switch control circuit 830 includes a third resistor R3, a fifth diode D5, and a fourth resistor R4 and a sixth diode D6 connected in series between the output terminal HI of the position sensor 820 and the control electrode G of the controllable bidirectional AC switch 826. An anode of the sixth diode D6 is connected to the control electrode G of the controllable bidirectional AC switch 826. One terminal of the third resistor R3 is connected to the high voltage output terminal C of the AC-DC conversion circuit 828, and the other terminal of the third resistor R3 is connected to an anode of the fifth diode D5. A cathode of the fifth diode D5 is connected to the control electrode G of the controllable bidirectional AC switch 826.

In conjunction with FIG. 6, an operational principle of the drive circuit 840 is described. In FIG. 6, Vac indicates a waveform of voltage of the AC power supply 824, and lac indicates a waveform of current flowing through the stator winding 816. Due to the inductive character of the stator winding 816, the waveform of current lac lags behind the waveform of voltage Vac. V1 indicates a waveform of voltage between two terminals of the first zener diode Z1, V2 indicates a waveform of voltage between two terminals of the second zener diode Z2, Vdc indicates a waveform of voltage between two output terminals C and D of the AC-DC conversion circuit 828, Ha indicates a waveform of a signal output by the output terminal H1 of the position sensor 820, and Hb indicates a rotor magnetic field detected by the position sensor 820. In this embodiment, in a case that the position sensor 820 is powered normally, the output terminal HI outputs a logic high level in a case that the detected rotor magnetic field is North, or the output terminal H1 outputs a logic low level in a case that the detected rotor magnetic field is South.

In a case that the rotor magnetic field Hb detected by the position sensor 820 is North, in a first positive half cycle of the AC power supply, the supply voltage is gradually increased from a time instant t0 to a time instant t1, the output terminal H1 of the position sensor 820 outputs a high level, and a current flows through the resistor R1, the resistor R3, the diode D5 and the control electrode G and the second anode T2 of the TRIAC 826 sequentially. The TRIAC 826 is switched on in a case that a drive current flowing through the control electrode G and the second anode T2 is greater than a gate triggering current Ig. Once the TRIAC 826 is switched on, the two nodes A and B are shorted, a current flowing through the stator winding 816 in the motor is gradually increased until a large forward current flows through the stator winding 816 to drive the rotor 814 to rotate clockwise as shown in FIG. 3. Since the two nodes A and B are shorted, there is no current flowing through the AC-DC conversion circuit 28 from the time instant t1 to a time instant t2. Hence, the resistors R1 and R2 do not consume electric energy, and the output of the position sensor 820 is stopped due to no power is supplied. Since the current flowing through two anodes T1 and T2 of the TRIAC 826 is large enough (which is greater than a holding current Ihold), the TRIAC 826 is kept to be switched on in a case that there is no drive current flowing through the control electrode G and the second anode T2. In a negative half cycle of the AC power supply, after a time instant t3, a current flowing through T1 and T2 is less than the holding current Ihold, the TRIAC 826 is switched off, a current begins to flow through the AC-DC conversion circuit 828, and the output terminal HI of the position sensor 820 outputs a high level again. Since a potential at the point C is lower than a potential at the point E, there is no drive current flowing through the control electrode G and the second anode T2 of the TRIAC 826, and the TRIAC 826 is kept to be switched off. Since the resistance of the resistors R1 and R2 in the AC-DC conversion circuit 828 are far greater than the resistance of the stator winding 816 in the motor, a current currently flowing through the stator winding 816 is far less than the current flowing through the stator winding 816 from the time instant t1 to the time instant t2 and generates very small driving force for the rotor 814. Hence, the rotor 814 continues to rotate clockwise due to inertia. In a second positive half cycle of the AC power supply, similar to the first positive half cycle, a current flows through the resistor R1, the resistor R3, the diode D5, and the control electrode G and the second anode T2 of the TRIAC 826 sequentially. The TRIAC 826 is switched on again, and the current flowing through the stator winding 816 continues to drive the rotor 814 to rotate clockwise. Similarly, the resistors R1 and R2 do not consume electric energy since the two nodes A and B are shorted. In the next negative half cycle of the power supply, the current flowing through the two anodes T1 and T2 of the TRIAC 826 is less than the holding current Ihold, the TRIAC 826 is switched off again, and the rotor continues to rotate clockwise due to the effect of inertia.

At a time instant t4, the rotor magnetic field Hb detected by the position sensor 820 changes to be South from North, the AC power supply is still in the positive half cycle and the TRIAC 826 is switched on, the two nodes A and B are shorted, and there is no current flowing through the AC-DC conversion circuit 828. After the AC power supply enters the negative half cycle, the current flowing through the two anodes T1 and T2 of the TRIAC 826 is gradually decreased, and the TRIAC 826 is switched off at a time instant t5. Then the current flows through the second anode T2 and the control electrode G of the TRIAC 826, the diode D6, the resistor R4, the position sensor 820, the resistor R2 and the stator winding 816 sequentially. As the drive current is gradually increased, the TRIAC 826 is switched on again at a time instant t6, the two nodes A and B are shorted again, the resistors RI and R2 do not consume electric energy, and the output of the position sensor 820 is stopped due to no power is supplied. There is a larger reverse current flowing through the stator winding 816, and the rotor 814 continues to be driven clockwise since the rotor magnetic field is South. From the time instant t5 to the time instant t6, the first zener diode Z1 and the second zener diode Z2 are switched on, hence, there is a voltage output between the two output terminals C and D of the AC-DC conversion circuit 828. At a time instant t7, the AC power supply enters the positive half cycle again, the TRIAC 826 is switched off when the current flowing through the TRIAC 826 crosses zero, and then a voltage of the control circuit is gradually increased. As the voltage is gradually increased, a current begins to flow through the AC-DC conversion circuit 828, the output terminal H1 of the position sensor 820 outputs a low level, there is no drive current flowing through the control electrode G and the second anode T2 of the TRIAC 826, hence, the TRIAC 826 is switched off. Since the current flowing through the stator winding 816 is very small, nearly no driving force is generated for the rotor 814. At a time instant t8, the power supply is in the positive half cycle, the position sensor outputs a low level, the TRIAC 826 is kept to be switched off after the current crosses zero, and the rotor continues to rotate clockwise due to inertia. According to an embodiment of the present invention, the rotor may be accelerated to be synchronized with the stator after rotating only one circle after the stator winding is energized.

In the embodiment of the present invention, by taking advantage of a feature of a TRIAC that the TRIAC is kept to be switched on although there is no drive current flowing though the TRIAC once the TRIAC is switched on, it is avoided that a resistor in the AC-DC conversion circuit still consumes electric energy after the TRIAC is switched on, hence, the utilization efficiency of electric energy can be improved significantly.

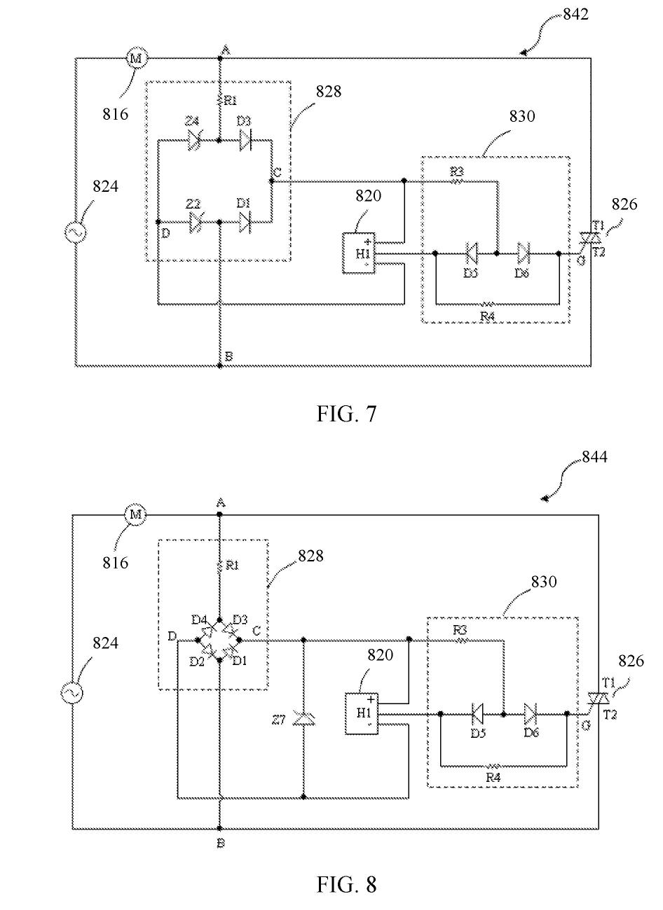

FIG. 7 shows a circuit diagram of a drive circuit 842 for a synchronous motor according to an embodiment of the present disclosure. The stator winding 816 of the synchronous motor is connected in series with the AC power supply 824 between the two nodes A and B. A first anode T1 of the TRIAC 826 is connected to the node A, and a second anode T2 of the TRIAC 826 is connected to the node B. The AC-DC conversion circuit 828 is connected in parallel with the TRIAC 826 between the two nodes A and B. An AC between the two nodes A and B is converted by the AC-DC conversion circuit 828 into a low voltage DC, preferably, a low voltage ranging from 3V to 18V. The AC-DC conversion circuit 828 includes a first resistor R1 and a full wave bridge rectifier connected in series between the two nodes A and B. The full wave bridge rectifier includes two rectifier branches connected in parallel, one of the two rectifier branches includes a first diode D1 and a third diode D3 reversely connected in series, and the other of the two rectifier branches includes a second zener diode Z2 and a fourth zener diode Z4 reversely connected in series, the high voltage output terminal C of the AC-DC conversion circuit 828 is formed at a connection point of a cathode of the first diode D1 and a cathode of the third diode D3, and the low voltage output terminal D of the AC-DC conversion circuit 828 is formed at a connection point of an anode of the second zener diode Z2 and an anode of the fourth zener diode Z4. The output terminal C is connected to a positive power supply terminal of the position sensor 820, and the output terminal D is connected to a negative power supply terminal of the position sensor 820. The switch control circuit 30 includes a third resistor R3, a fourth resistor R4, and a fifth diode D5 and a sixth diode D6 reversely connected in series between the output terminal H1 of the position sensor 820 and the control electrode G of the controllable bidirectional AC switch 826. A cathode of the fifth diode D5 is connected to the output terminal H1 of the position sensor, and a cathode of the sixth diode D6 is connected to the control electrode G of the controllable bidirectional AC switch. One terminal of the third resistor R3 is connected to the high voltage output terminal C of the AC-DC conversion circuit, and the other terminal of the third resistor R3 is connected to a connection point of an anode of the fifth diode D5 and an anode of the sixth diode D6. Two terminals of the fourth resistor R4 are connected to a cathode of the fifth diode D5 and a cathode of the sixth diode D6 respectively.

FIG. 8 shows a circuit diagram of a drive circuit 844 for a synchronous motor according to a further embodiment of the present invention. The drive circuit 844 is similar to the drive circuit 842 in the previous embodiment and, the drive circuit 844 differs from the drive circuit 842 in that, the zener diodes Z2 and Z4 in the drive circuit 842 are replaced by general diodes D2 and D4 in the rectifier of the drive circuit 844. In addition, a zener diode Z7 is connected between the two output terminals C and D of the AC-DC conversion circuit 828 in the drive circuit 844.

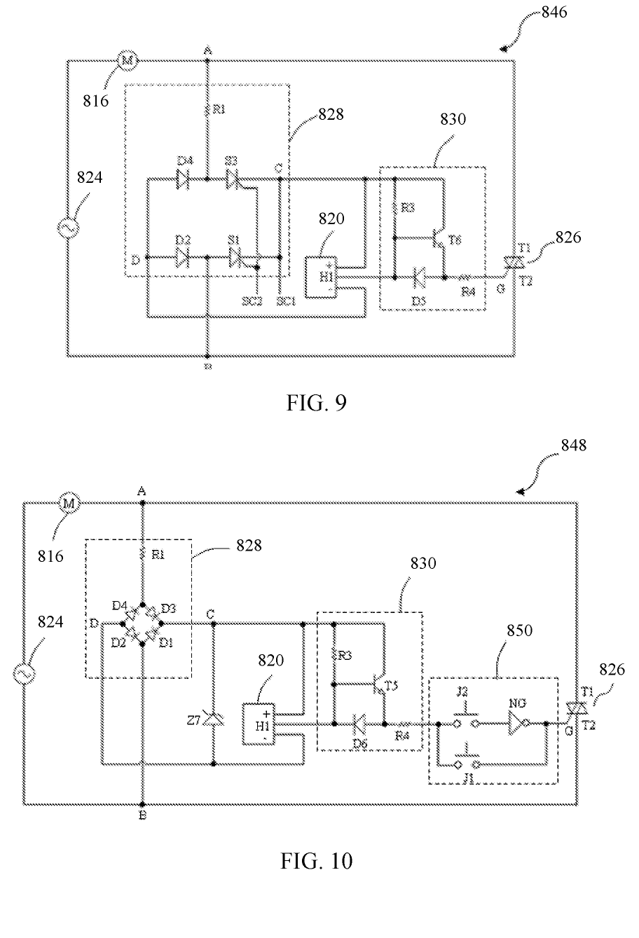

FIG. 9 shows a circuit diagram of a drive circuit 846 for a synchronous motor according to further embodiment of the present invention. The stator winding 816 of the synchronous motor is connected in series with the AC power supply 824 between the two nodes A and B. A first anode Ti of the TRIAC 826 is connected to the node A, and a second anode T2 of the TRIAC 826 is connected to the node B. The AC-DC conversion circuit 828 is connected in parallel with the TRIAC 826 between the two nodes A and B. An AC voltage between the two nodes A and B is converted by the AC-DC conversion circuit 828 into a low voltage DC, preferably, a low voltage ranging from 3V to 18V. The AC-DC conversion circuit 828 includes a first resistor R1 and a full wave bridge rectifier connected in series between the two nodes A and B. The full wave bridge rectifier includes two rectifier branches connected in parallel, one of the two rectifier branches includes two silicon control rectifiers S1 and S3 reversely connected in series, and the other of the two rectifier branches includes a second diode D2 and a fourth diode D4 reversely connected in series. The high voltage output terminal C of the AC-DC conversion circuit 828 is formed at a connection point of a cathode of the silicon control rectifier S1 and a cathode of the silicon control rectifier S3, and the low voltage output terminal D of the AC-DC conversion circuit 828 is formed at a connection point of an anode of the second diode D2 and an anode of the fourth diode D4. The output terminal C is connected to a positive power supply terminal of the position sensor 820, and the output terminal D is connected to a negative power supply terminal of the position sensor 820. The switch control circuit 830 includes a third resistor R3, an NPN transistor T6, and a fourth resistor R4 and a fifth diode D5 connected in series between the output terminal H1 of the position sensor 820 and the control electrode G of the controllable bidirectional AC switch 826. A cathode of the fifth diode D5 is connected to the output terminal Hl of the position sensor. One terminal of the third resistor R3 is connected to the high voltage output terminal C of the AC-DC conversion circuit, and the other terminal of the third resistor R3 is connected to the output terminal H1 of the position sensor. A base of the NPN transistor T6 is connected to the output terminal H1 of the position sensor, an emitter of the NPN transistor T6 is connected to an anode of the fifth diode D5, and a collector of the NPN transistor T6 is connected to the high voltage output terminal C of the AC-DC conversion circuit.

In this embodiment, a reference voltage may be input to the cathodes of the two silicon control rectifiers S1 and S3 via a terminal SC1, and a control signal may be input to control terminals of S1 and S3 via a terminal SC2. The rectifiers Si and S3 are switched on in a case that the control signal input from the terminal SC2 is a high level, or are switched off in a case that the control signal input from the terminal SC2 is a low level. Based on the configuration, the rectifiers S1 and S3 may be switched between a switch-on state and a switch-off state in a preset way by inputting the high level from the terminal SC2 in a case that the drive circuit operates normally. The rectifiers S1 and S3 are switched off by changing the control signal input from the terminal SC2 from the high level to the low level in a case that the drive circuit fails. In this case, the TRIAC 826, the conversion circuit 828 and the position sensor 820 are switched off, to ensure the whole circuit to be in a zero-power state.

FIG. 10 shows a circuit diagram of a drive circuit 848 for a synchronous motor according to another embodiment of the present invention. The drive circuit 848 is similar to the drive circuit 846 in the previous embodiment and, the drive circuit 848 differs from the drive circuit 846 in that, the silicon control diodes S1 and S3 in the drive circuit 846 are replaced by general diodes D1 and D3 in the rectifier of the drive circuit 848, and a zener diode Z7 is connected between the two terminals C and D of the AC-DC conversion circuit 828. In addition, in the drive circuit 848 according to the embodiment, a preset steering circuit 850 is disposed between the switch control circuit 30 and the TRIAC 826. The preset steering circuit 850 includes a first jumper switch J1, a second jumper J2 switch and an inverter NG connected in series with the second jumper switch J2. Similar to the drive circuit 846, in this embodiment, the switch control circuit 830 includes the resistor R3, the resistor R4, the NPN transistor T5 and the diode D6. One terminal of the resistor R4 is connected to a connection point of an emitter of the transistor T5 and an anode of the diode D6, and the other terminal of the resistor R4 is connected to one terminal of the first jumper switch J1, and the other terminal of the first jumper switch J1 is connected to the control electrode G of the TRIAC 826, and the second jumper switch J2 and the inverter NG connected in series are connected across two terminals of the first jumper switch J1. In this embodiment, when the first jumper switch J1 is switched on and the second jumper switch J2 is switched off, similar to the above embodiments, the rotor 814 still starts clockwise; when the second jumper switch J2 is switched on and the first jumper switch J1 is switched off, the rotor 814 starts counterclockwise. In this case, a starting direction of the rotor in the motor may be selected by selecting one of the two jumper switches to be switched on and the other to be switched off. Therefore, in a case that a driving motor is needed to be supplied for different applications having opposite rotational directions, it is just needed to select one of the two jumper switches J1 and J2 to be switched on and the other to be switched off, and no other changes need to be made to the drive circuit, hence, the drive circuit according to this embodiment has good versatility.

As discussed above, the position sensor 820 is configured for detecting the magnetic pole position of the permanent magnet rotor 814 of the synchronous motor 810 and outputting a corresponding signal. The output signal from the position sensor 820 represents some characteristics of the magnetic pole position such as the polarity of the magnetic field associated with the magnetic pole position of the permanent magnet rotor 814 of the synchronous motor 810. The detected magnetic pole position is then used, by the switch control circuit 830, control the controllable bidirectional AC switch 824 to be switched between a switch-on state and a switch-off state in a predetermined way, based on, together with the magnetic pole position of the permanent magnet rotor, the polarity information of the AC power supply 824 which may be obtained from the AC-DC conversion circuit 828. It should be appreciated that the switch control circuit 830 and the position sensor 820 can be realized via magnetic sensing. Accordingly, the present disclosure discloses a magnetic sensor integrated circuit for magnetic sensing and control of a motor according to the sensed information.

The magnetic sensor integrated circuit according to the present disclosure includes a magnetic field detecting circuit that can reliably detect a magnetic field and generate a magnetic induction signal indicative of certain characteristics of the magnetic field. The magnetic sensor as disclosed herein also includes an output control circuit that controls the magnetic sensor to operate in a state determined with respect to the polarity of the magnetic field as well as that of an AC power supply. In the case the magnetic sensor integrated circuit is coupled with the bidirectional AC switch, the magnetic sensor integrated circuit can effectively regulate the operation of the motor via the bidirectional AC switch. Further, the magnetic sensor integrated circuit in the present disclosure may be directly connected to a commercial/residential AC power supply with no need for any additional A/D converting equipment. In this way, the present disclosure of the magnetic sensor integrated circuit is suitable to be used in a wide range of applications.

Additional novel features associated with the magnetic sensor integrated circuit disclosed herein will be set forth in part in the description which follows, and in part will become apparent to those skilled in the art upon examination of the following and the accompanying drawings or may be learned by production or operation of the examples. The novel features of the present disclosure on a magnetic sensor integrated circuit may be realized and attained by practice or use of various aspects of the methodologies, instrumentalities and combinations set forth in the detailed examples discussed below. The disclosed magnetic sensor integrated circuit, and a motor assembly incorporating the magnetic sensor integrated circuit and an application device disclosed herein can be achieved realized based on any circuit technology known to one of ordinary skill in the art including but not limited to the integrated circuit and other circuit implementations.

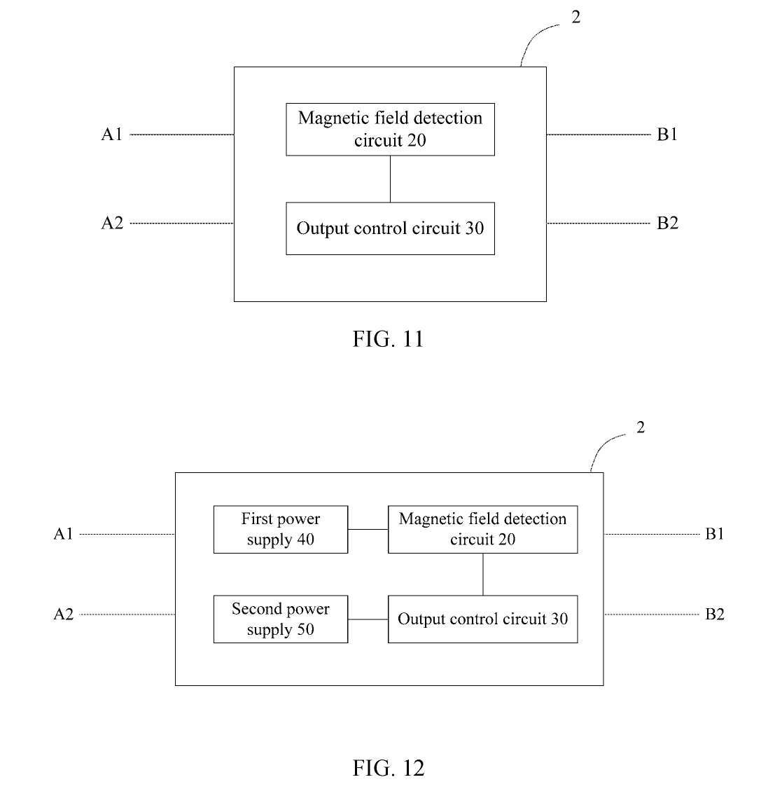

As shown in FIG. 11, a magnetic sensor integrated circuit is provided according to an embodiment of the disclosure. The magnetic sensor integrated circuit includes a housing 2, a semiconductor substrate (not shown) arranged in the housing 2, an electronic circuit arranged on the semiconductor substrate, and input ports A1 and A2, a first output port B1 and a second output port B2 extending out from the housing 2. The electronic circuit includes:

a magnetic field detection circuit 20 configured to detect an external magnetic field and generate magnetic field detection information, where the first output port B1 is connected to the magnetic field detection circuit 20 for outputting the magnetic field detection information to an outside of the housing; and

an output control circuit 30 configured to control, based at least on the magnetic field detection information, the integrated circuit to operate in at least one of a first state in which a current flows from the second output port B2 to an outside of the integrated circuit and a second state in which a current flows from the outside of the integrated circuit to the second output port B2.

In a preferred embodiment of the disclosure based on the embodiment above, the output control circuit 30 is configured to control, based at least on the magnetic field detection information, the integrated circuit to switch between a first state in which a load current flows from the second output port to the outside of the integrated circuit and a second state in which a load current flows from the outside of the integrated circuit to the second output port. An outflow current and an inflow current both flow through a rectifying circuit, as the case may be, which is not limited in the disclosure.

It should be noted that, in an embodiment of the disclosure, the switching of the magnetic sensor integrated circuit between the first state and the second state is not limited to a case that the magnetic sensor integrated circuit switches to a state as soon as the other state ends, but further includes a case that the magnetic sensor integrated circuit waits for an interval time to switch to a state after the other state ends. In a preferred embodiment, there is no output in the output ports of the magnetic sensor integrated circuit within the interval time in switching between the two states.

In an embodiment of the disclosure, as shown in FIG. 12, the electronic circuit further includes a first power supply 40 and a second power supply 50. The magnetic field detection circuit 20 is powered by the first power supply 40, and the output control circuit 30 is powered by the second power supply 50 different from the first power supply 40. Preferably, an average of an output voltage of the first power supply 40 is smaller than that of an output voltage of the second power supply 50. It should be noted that the magnetic field detection circuit 20 is powered by a power supply with low power consumption, which can reduce power consumption of the integrated circuit. The output control circuit 30 is powered by a power supply with high power consumption, which can control the second output port to provide a high load current to guarantee sufficient drive capability of the integrated circuit.

In an embodiment of the disclosure based on the embodiment described above, the output control circuit 30 includes a first switch and a second switch. The first switch and the second output port are connected in a first current path, the second switch and the second output port are connected in a second current path having a direction opposite to that of the first current path, and the first switch and the second switch are turned on selectively based on the magnetic field detection information. Preferably, the first switch may be a triode, and the second switch may be a triode or a diode, as the case may be, which is not limited in the disclosure.

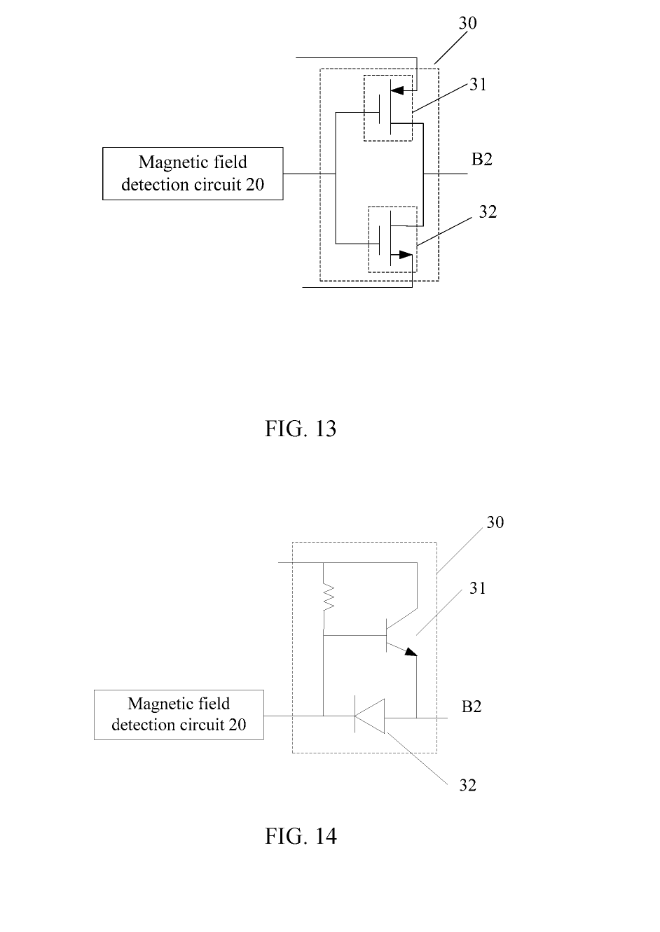

In a specific embodiment of the disclosure, as shown in FIG. 13, the first switch 31 is turned on at a low level, and the second switch 32 is turned on at a high level. The first switch 31 and the second output port B2 are connected in the first current path. The second switch 32 and the second output port B2 are connected in the second current path. Control terminals of the first switch 31 and the second switch 32 are both connected to the magnetic field detection circuit 20. A current input terminal of the first switch 31 is connected to a high voltage (for example, a DC power supply), a current output terminal of the first switch 31 is connected to a current input terminal of the second switch 32, and a current output terminal of the second switch 32 is connected to a low voltage (for example, the ground). In a case that the magnetic field detection information outputted from the magnetic field detection circuit 20 is a low level, the first switch 31 is turned on, and the second switch 32 is turned off, so that a load current flows out from the high voltage end through the first switch 31 and the second output port B2. In a case that the magnetic field detection information outputted from the magnetic field detection circuit 20 is a high level, the second switch 32 is turned on, and the first switch 31 is turned off, so that the load current flows from outside of the integrated circuit to the second output port B2 through the second switch 32.

In another embodiment of the disclosure, as shown in FIG. 14, the first switch 31 is a switch transistor which is turned on at a high level, the second switch 32 is a unidirectional diode, and the control terminal of the first switch 31 and a cathode of the second switch 32 are connected to the magnetic field detection circuit 20. The current input terminal of the first switch 31 is connected to the second power supply 50, and the current output terminal of the first switch 31 and an anode of the second switch 32 are both connected to the second output port B2. The first switch 31 and the second output port B2 are connected in a first current path, and the second output port B2, the second switch 32 and the magnetic field detection circuit 20 are connected in a second current path. In a case that the magnetic field detection information outputted from the magnetic field detection circuit 20 is a high level, the first switch 31 is turned on, and the second switch 32 is turned off, so that the load current flows out from the second power supply 50 through the first switch 31 and the second output port B2. In a case that the magnetic field detection information outputted from the magnetic field detection circuit 20 is a low level, the second switch 32 is turned on, and the first switch 31 is turned off, so that the load current flows from outside of the integrated circuit to the second output port B2 through the second switch 32. It is understood that in other embodiments of the disclosure, the first switch 31 and the second switch 32 may have other structures, as the case may be, which is not limited in the disclosure.

In another embodiment of the disclosure, the output control circuit 30 includes a first current path in which a current flows out from an output port, a second current path in which a current flows in from the output port and a switch connected in one of the first current path and the second current path. The switch is configured to control, based on the magnetic field detection information outputted from the magnetic field detection circuit, the first current path and the second current path to be turned on selectively. Preferably, the other of the first current path and the second current path is not provided with a switch.

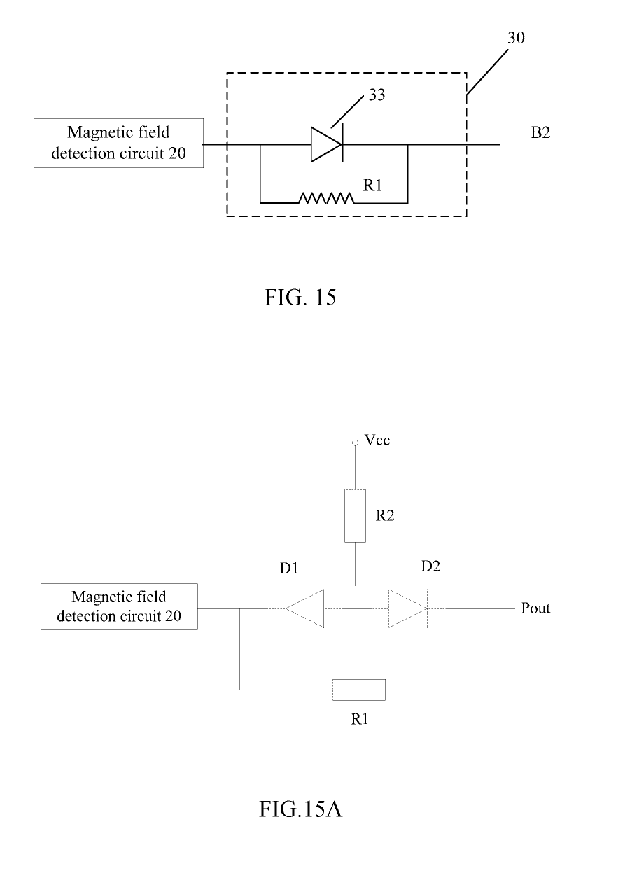

In a specific implementation, as shown in FIG. 15, the output control circuit 30 includes a unidirectional switch 33. The unidirectional switch 33 and the second output port B2 are connected in the first current path, a current input terminal of the unidirectional switch 33 may be connected to an output terminal of the magnetic field detection circuit 20, and the output terminal of the magnetic field detection circuit 20 may be connected in the second current path having a direction opposite to that of the first current path through a resistor R1 and the second output port B2. The unidirectional switch 33 is turned on when a magnetic field induction signal is at a high level, so that the load current flows out through the unidirectional switch 33 and the second output port B2. The unidirectional switch 33 is turned off when the magnetic field induction signal is at a low level, so that the load current flows from outside of the integrated circuit to the second output port B2 through the resistor R1 and the magnetic field detection circuit 20. Alternatively, the resistor R1 in the second current path may be replaced by another unidirectional switch connected in reverse-parallel to the unidirectional switch 33. In this way, load currents flowing out and in through the output port can be balanced.

In another specific implementation, as shown in FIG. 15A, the output control circuit 30 includes diodes D1 and D2 connected in reverse-series between the output terminal of the magnetic field detection circuit 20 and an output port Pout, a resistor R1 connected in parallel to the diodes D1 and D2 connected in series, and a resistor R2 connected between a common terminal of the diodes D1 and D2 and a power supply Vcc. A cathode of the diode D1 is connected to the output terminal of the magnetic field detection circuit 20. The power supply Vcc may be connected to a voltage output terminal of the rectifying circuit. The diode D1 is controlled based on the magnetic field detection information. In a case that the magnetic field detection information is a high level, the diode D1 is turned off, and the load current flows out from the output port Pout through the resistor R2 and the diode D2. In a case that the magnetic field detection information is a low level, the load current flows from outside of the integrated circuit to the output port Pout through the resistor R1 and the magnetic field detection circuit 20.

In an embodiment of the disclosure based on any of the embodiments above, the input ports include the first input port A1 and the second input port A2 configured to connect an external AC power supply to the magnetic sensor integrated circuit, and the output control circuit controls, based on a polarity of the AC power supply and the magnetic field detection information, the integrated circuit to switch between at least the first state and the second state. Optionally, the magnetic field detection circuit 20 and the output control circuit 30 are powered by a same one power supply.

In an embodiment of the disclosure based on any of the embodiments above, the output control circuit 30 is configured to control the load current to flow through the second output port in a case that the AC power supply is in a positive half cycle and the external magnetic field is detected by the magnetic field detection circuit 20 to have a first polarity or in a case that the AC power supply is in a negative half cycle and the external magnetic field is detected by the magnetic field detection circuit 20 to have a second polarity opposite to the first polarity, or control no load current to flow through the second output port in a case that the AC power supply is in a positive half cycle and the external magnetic field is detected by the magnetic field detection circuit to have a second polarity or in a case that the AC power supply is in a negative half cycle and the external magnetic field is detected by the magnetic field detection circuit to have a first polarity opposite to the second polarity. It should be noted that in a case that the AC power supply is in a positive half cycle and the external magnetic field has the first polarity or in a case that the AC power supply is in a negative half cycle and the external magnetic field has the second polarity, the load current may flow through the second output port in both of the above two cases, or only for a part of time in either of the above two cases.

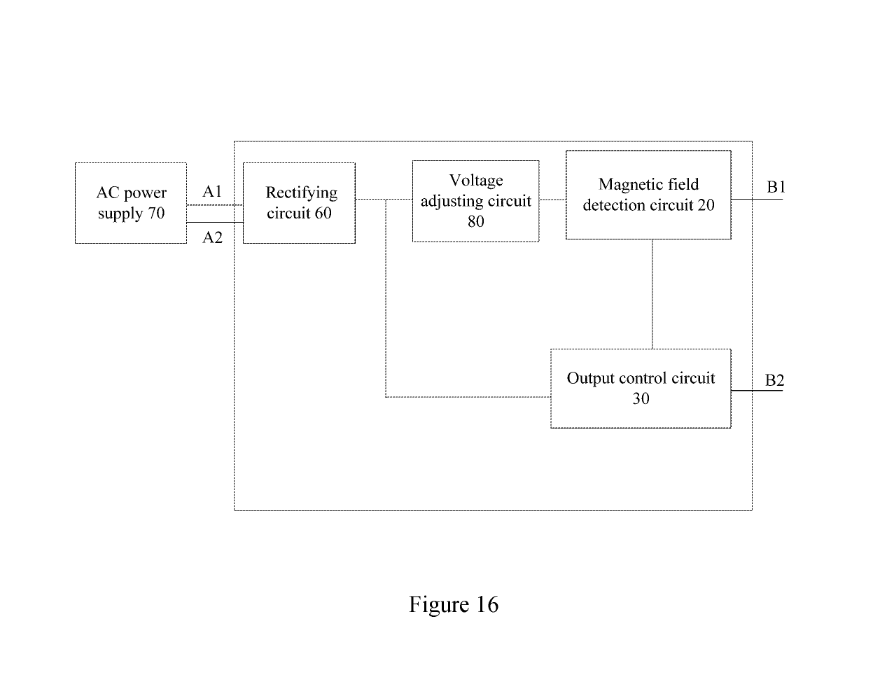

In an embodiment of the disclosure based on the embodiments above, the input ports may include the first input port A1 and the second input port A2 connecting the external AC power supply to the magnetic integrated circuit. In the disclosure, connecting of the input ports and the external power supply includes a case that the input ports are directly connected across the external AC power supply as well as a case that the input ports and an external load are connected in series across the external AC power supply, as the case may be, which is not limited in the disclosure. As shown in FIG. 16, in an embodiment of the disclosure, the integrated circuit further includes a rectifying circuit 60 configured to convert an alternating current outputted from the external AC power supply 70 into a direct current.

It should be noted that in the embodiment of the disclosure, the rectifying circuit 60 is connected to the output control circuit 30, and the output control circuit 30 may be configured to control, based at least on the magnetic field detection information, the integrated circuit to operate in at least one of the first state in which a current flows from the second output port to the outside of the integrated circuit and the second state in which a current flows from the outside of the integrated circuit to the second output port.

In a preferred embodiment of the disclosure based on the embodiments above, the integrated circuit further includes a voltage adjusting circuit 80 arranged between the rectifying circuit 60 and the magnetic field detection circuit 20. In the embodiment, the rectifying circuit 60 may function as the second power supply 50, and the voltage adjusting circuit 80 may function as the first power supply 40, and configured to adjust a first voltage outputted from the rectifying circuit 60 to a second voltage. The second voltage is a supply voltage of the magnetic field detection circuit 20, the first voltage is a supply voltage of the output control circuit 30, and an average of the first voltage is greater than that of the second voltage, to reduce power consumption of the integrated circuit and guarantee sufficient drive capability of the integrated circuit.

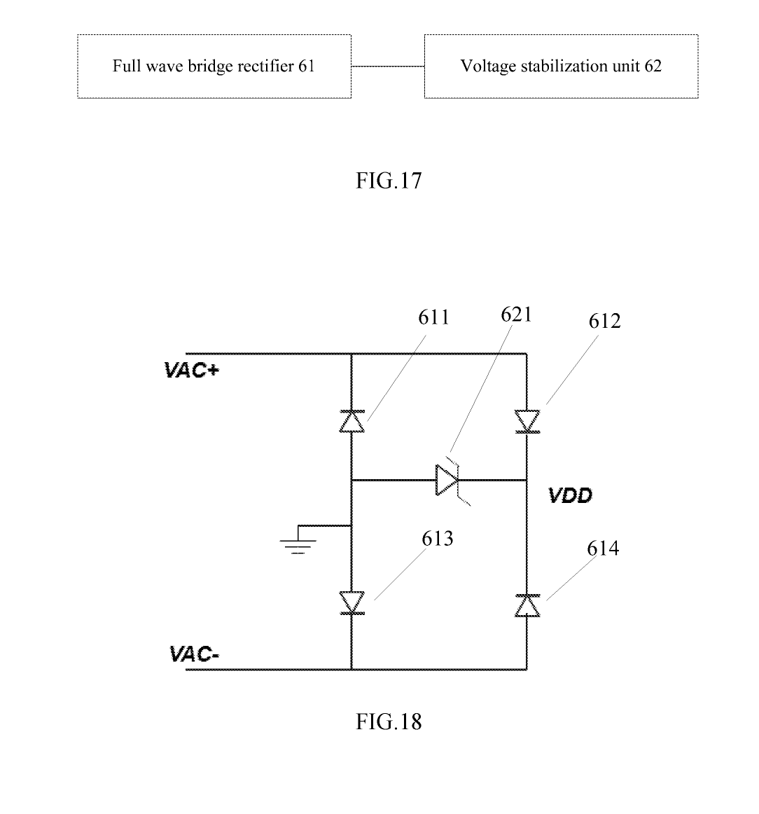

In a specific embodiment of the disclosure, as shown in FIG. 17, the rectifying circuit 60 includes a full wave bridge rectifier 61 and a voltage stabilization unit 62 connected to an output terminal of the full wave bridge rectifier 61. The full wave bridge rectifier 61 is configured to convert an alternating current outputted from the AC power supply 70 into a direct current, and the voltage stabilization unit 62 is configured to stabilize the direct current outputted from the full wave bridge rectifier 61 within a predetermined range.

FIG. 18 shows a specific implementation of the rectifying circuit 60. The voltage stabilization unit 62 includes a voltage stabilization diode 621 connected between two output terminals of the full wave bridge rectifier 61. The full wave bridge rectifier 61 includes a first diode 611 and a second diode 612 connected in series, and a third diode 613 and a fourth diode 614 connected in series. A common terminal of the first diode 611 and the second diode 612 is electrically connected to the first input port VAC+, and a common terminal of the third diode 613 and the fourth diode 614 is electrically connected to the second input port VAC−.

An input terminal of the first diode 611 is electrically connected to an input terminal of the third diode 613 to form a ground output terminal of the full wave bridge rectifier, an output terminal of the second diode 612 is electrically connected to an output terminal of the fourth diode 614 to form a voltage output terminal VDD of the full wave bridge rectifier, and the voltage stabilization diode 621 is connected between a common terminal of the second diode 612 and the fourth diode 614 and a common terminal of the first diode 611 and the third diode 613. It should be noted that a power terminal of the output control circuit 30 may be connected to the voltage output terminal of the full wave bridge rectifier 61.

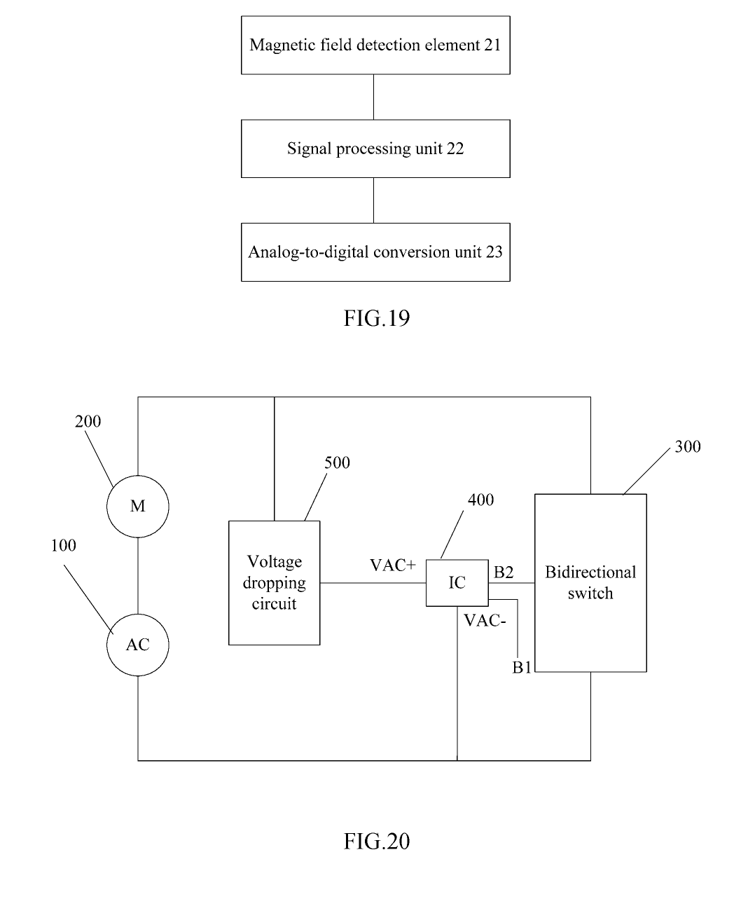

In an embodiment of the disclosure based on any of the embodiments above, as shown in FIG. 19, the magnetic field detection circuit 20 includes: a magnetic field detection element 21 configured to detect the external magnetic field and convert the same into an electrical signal; a signal processing unit 22 configured to amplify and descramble the electrical signal; and an analog-to-digital conversion unit 23 configured to convert the amplified and descrambled electrical signal into the magnetic field detection information. For an application only requiring recognition of a polarity of the external magnetic field, the magnetic field detection information may be a switch-type digital signal. Preferably, the magnetic field detection element 21 may be a Hall plate. In the embodiment, an output terminal of the analog-to-digital conversion unit 23 is connected to the output control circuit 30 and the first output port B1. The output control circuit 30 may process the magnetic field detection information inside the magnetic sensor integrated circuit, and generate a desired output at the second output port B2, and the magnetic field detection information outputted from the first output port B1 may be provided for an external circuit of the magnetic sensor integrated circuit.

In a preferred embodiment, in a case that the input ports include the first input port and the second input port configured to connect the external AC power supply to the magnetic sensor integrated circuit, an occurrence frequency of the first state or the second state is proportional to a frequency of the AC power supply, which is not limited in the disclosure, as should be understood.

The magnetic sensor integrated circuit according to the disclosure is described in conjunction with a specific application.

As shown in FIG. 20, a motor assembly is provided according to an embodiment of the disclosure. The motor assembly includes: a motor 200 powered by an AC power supply 100; a bidirectional switch 300 connected in series with the motor 200; and the magnetic sensor integrated circuit 400 according to any of the embodiments of the disclosure above. The second output port B2 of the magnetic sensor integrated circuit 400 is connected to a control terminal of the bidirectional switch 300. Preferably, the bidirectional switch 300 may be a triode AC semiconductor switch (TRIAC). It is understood that the bidirectional switch may be implemented with any other appropriate switch, which, for example, may include two silicon controlled rectifiers connected in reverse-parallel, and a control circuit configured to control the two silicon controlled rectifiers in a predetermined manner based on the output signal from the output port of the magnetic sensor integrated circuit. Preferably, the motor assembly further includes a voltage dropping circuit 500 configured to reduce an output voltage of the AC power supply 100 and provide the reduced voltage for the magnetic sensor integrated circuit 400. The magnetic sensor integrated circuit 400 is arranged near a rotor of the motor 200 to sense change in a magnetic field of the rotor.

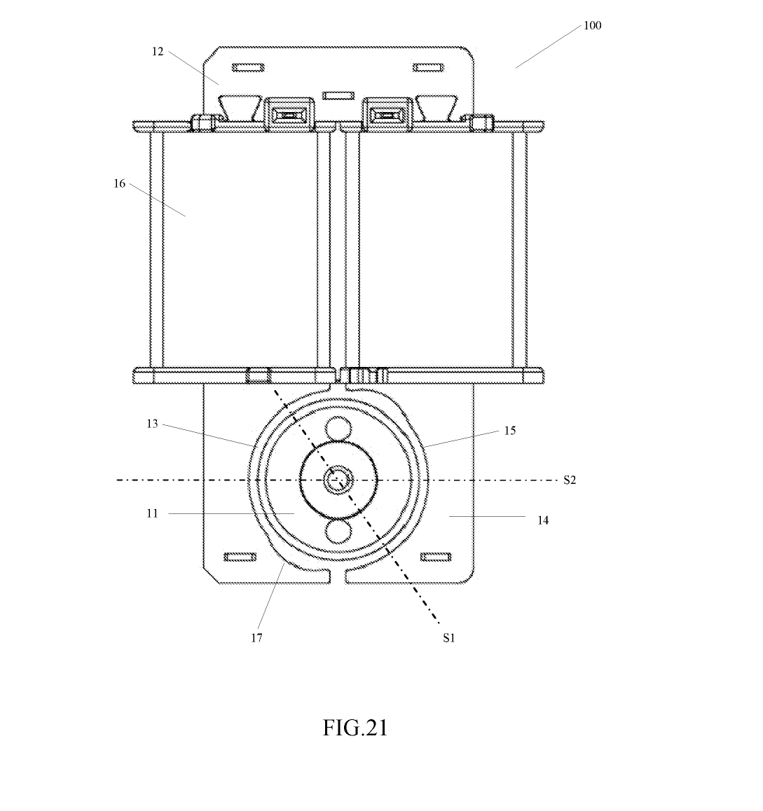

In a specific embodiment of the disclosure based on the embodiment above, the motor is a synchronous motor, and it is understood that the magnetic sensor integrated circuit not only applies to a synchronous motor, but also applies to other suitable types of permanent motors such as a DC brushless motor. As shown in FIG. 21, the synchronous motor includes a stator and a rotor 11 rotatable relative to the stator. The stator includes a stator core 12 and a stator winding 16 wound on the stator core 12. The stator core 12 may be made of soft magnetic materials such as pure iron, cast iron, cast steel, electrical steel and silicon steel. The rotor 11 includes a permanent magnet. The rotor 11 operates at a constant rotational speed of 60 f/p revs/min during a steady state phase in a case that the stator winding 16 is connected in series with an AC power supply, where f is a frequency of the AC power supply and p is the number of pole pairs of the rotor. In the embodiment, the stator core 12 includes two poles 14 opposite to each other. Each of the poles 14 includes a pole arc 15, an outer surface of the rotor 11 is opposite to the pole arc 15, and a substantially uniform air gap is formed between the outer surface of the rotor 11 and the pole arc 15. The “substantially uniform air gap” in the disclosure means that a uniform air gap 13 is formed in most space between the stator and the rotor, and a non-uniformed air gap is formed in a small part of the space between the stator and the rotor. Preferably, a starting groove 17 which is concave may be disposed in the pole arc 15 of the pole of the stator, and a part of the pole arc 15 rather than the starting groove 17 may be concentric with the rotor. With the configuration described above, the non-uniform magnetic field may be formed, a polar axis S1 of the rotor has an angle of inclination relative to a central axis S2 of the pole of the stator in a case that the rotor is at rest, and the rotor may have a starting torque every time the motor is energized under the action of the integrated circuit. Specifically, the “pole axis S1 of the rotor” refers to a boundary between two magnetic poles having different polarities, and the “central axis S2 of the pole 14 of the stator” refers to a connection line passing central points of the two poles 14 of the stator. In the embodiment, both the stator and the rotor include two magnetic poles. It can be understood that the number of magnetic poles of the stator may not be equal to the number of magnetic poles of the rotor, and the stator and the rotor may have more magnetic poles, such as 4 or 6 magnetic poles in other embodiments. It should be understandable that other type of non-uniformed air gap may be alternatively formed between the rotor and the stator.

In an embodiment of the disclosure based on the embodiment above, the magnetic sensor integrated circuit 30 is configured to control the bidirectional switch 300 to be turned on in a case the AC power supply 100 is in a positive half cycle and a magnetic field of the permanent rotor is detected by the magnetic field detection circuit 20 to have a first polarity or in a case that the AC power supply 100 is in a negative half cycle and a magnetic field of the permanent rotor is detected by the magnetic field detection circuit 20 to have a second polarity opposite to the first polarity, or control the bidirectional switch 300 to be turned off in a case that the AC power supply 100 is in a negative half cycle and a magnetic field of the permanent rotor is detected by the magnetic field detection circuit to have a first polarity or in a case that the AC power supply 100 is in a positive half cycle and a magnetic field of the permanent rotor is detected by the magnetic field detection circuit to have a second polarity opposite to the first polarity.

Preferably, the output control circuit 30 is configured to control a current to flow from the integrated circuit to the bidirectional switch 300 in a case that a signal outputted from the AC power supply 100 is in a positive half cycle and a magnetic field of the permanent rotor is detected by the magnetic field detection circuit 20 to have the first polarity, or control a current to flow from the bidirectional switch 300 to the integrated circuit in a case that a signal outputted from the AC power supply 100 is in a negative half cycle and a magnetic field of permanent rotor is detected by the magnetic field detection circuit 20 to have a second polarity opposite to the first polarity. It is understood that in a case the permanent rotor has the first polarity and the AC power supply is in a positive half cycle, or in a case that the permanent rotor has the second polarity and the AC power supply is in a negative half cycle, the current flowing out from or into the integrated circuit includes the case in which there is a load current flowing through for the entire time period and the case in which there is a load current flowing through for only part of the time period.

In a preferred embodiment of the disclosure, the bidirectional switch 300 is implemented as a triode AC semiconductor switch (TRIAC), the rectifying circuit 60 is implemented as a circuit as shown in FIG. 18, and the output control circuit is implemented as a circuit as shown in FIG. 14. A current input terminal of the first switch 31 in the output control circuit 30 is connected to the voltage output terminal of the full wave bridge rectifier 61, and a current output terminal of the second switch 32 is connected to the ground output terminal of the full wave bridge rectifier 61. In a case that a signal outputted from the AC power supply 100 is in a positive half cycle and the magnetic field detection circuit 20 outputs a low level, the first switch 31 is turned on and the second switch 32 is turned off in the output control circuit 30, and a current flows through the AC power supply 100, the motor 200, a first input terminal of the integrated circuit 400, a voltage dropping circuit, an output terminal of the second diode 612 of the full wave bridge rectifier 61, the first switch 31 of the output control circuit 30 in turn, from the second output port to the bidirectional switch 300 and back to the AC power supply 100. When the TRIAC 300 is turned on, a series branch formed by the voltage dropping circuit 500 and the magnetic sensor integrated circuit 400 is shorted, and the magnetic sensor integrated circuit 400 stops outputting because there is no supply voltage, while the TRIAC 300 is still on in a case that there is no drive current between a control electrode and a first anode thereof, because a current which flows between two anodes thereof is high enough (higher than a holding current thereof). In a case that the signal inputted by the AC power supply 100 is in a negative half cycle and the magnetic field detection circuit 20 outputs a high level, the first switch 31 is turned off and the second switch 32 is turned on, and the current flows from the AC power supply 100, from the bidirectional switch 300 to the second output port, through the second switch 32 of the output control circuit 30, the ground output terminal and the first diode 611 of the full wave bridge rectifier 61, the first input terminal of the integrated circuit 400, the motor 200 and back to the AC power supply 100. Similarly, when the TRIAC 300 is turned on, the magnetic sensor integrated circuit 400 stops outputting for being shorted, while the TRIAC 300 is still on. In a case that a signal outputted from the AC power supply 100 is in a positive half cycle and the magnetic field detection circuit 20 outputs a high level, or in a case that the signal outputted from the AC power supply 100 is in a negative half cycle and the magnetic field detection circuit 20 outputs a low level, the first switch 31 and the second switch 32 in the output control circuit 30 are both turned off and the TRIAC 300 is turned off. In this way, the output control circuit 30 can control, based on a polarity of the AC power supply 100 and the magnetic field detection information, the integrated circuit to control the bidirectional switch 300 to be switched between a turn-on state and a turn-off state in a predetermined way, thereby controlling an energizing mode of the stator winding 16 so that changed magnetic field generated by the stator fits a position of a magnetic field of the rotor and drags the rotor to rotate in a single direction, thereby enabling the rotor to rotate in a fixed direction every time the motor is energized.

The magnetic sensor integrated circuit according to the embodiment of the disclosure includes at least four ports extending out from the housing, including the input ports, the first output port and the second output port. More preferably, the magnetic sensor integrated circuit according to the embodiment of the disclosure includes exactly includes four ports, i.e., the first input port, the second input port, the first output port and the second output port.

In a motor assembly according to another embodiment of the disclosure, the motor and the bidirectional switch may be connected in series across the external AC power supply, and a first series branch formed by the motor and the bidirectional switch is connected in parallel to a second series branch formed by the voltage dropping circuit and the magnetic sensor integrated circuit. The output port of the magnetic sensor integrated circuit is connected to the bidirectional switch, to control the bidirectional switch to switch between the turn-on state and the turn-off state in a predetermined way, thereby controlling the energizing mode of the stator winding.

The motor assembly according to the embodiment of the disclosure may be applied to, but not limited to, a pump, a fan, a household appliance and a vehicle, where the household appliance may be a washing machine, a dish-washing machine, a range hood or an exhaust fan, for example.

It should be noted that, an application field of the integrated circuit according to the disclosure is not limited herein, although the embodiments according to the disclosure are explained by taking the integrated circuit being applied to the motor as an example.

It should be noted that, the parts in this specification are described in a progressive manner, each of which emphasizes the differences from the others, and the same or similar parts among the parts can be referred to each other.

It should be noted that the relationship terminologies such as “first”, “second” and the like are only used herein to tell one entity or operation from another, rather than to necessitate or imply that an actual relationship or order exists between the entities or operations. Furthermore, terms of “include”, “comprise” or any other variants are intended to be non-exclusive. Therefore, a process, method, article or device including a plurality of elements includes not only the disclosed elements, but also includes other elements that are not clearly enumerated or further includes inherent elements of the process, method, article or device. Unless expressively limited otherwise, the statement “including a . . . ” does not exclude the case that other similar elements may exist in the process, method, article or device other than enumerated elements.

The description of the embodiments herein enables those skilled in the art to implement or use the disclosure. Numerous modifications to the embodiments are apparent to those skilled in the art, and the general principles defined herein can be implemented in other embodiments without deviating from the spirit or scope of the disclosure. Therefore, the disclosure may not be limited to the embodiments described herein, but is in accordance with the widest scope consistent with the principles and novel features disclosed herein.

1. A magnetic sensor integrated circuit, comprising:
a housing,
a semiconductor substrate arranged in the housing,
an electronic circuit arranged on the semiconductor substrate, and
input ports, a first output port and a second output port extending out from the housing, wherein the electronic circuit comprises:
a magnetic field detection circuit configured to detect an external magnetic field and generate magnetic field detection information, wherein the first output port is connected to the magnetic field detection circuit for outputting the magnetic field detection information to an outside of the housing; and
an output control circuit configured to control, based at least on the magnetic field detection information, the integrated circuit to operate in at least one of a first state in which a current flows from the second output port to an outside of the integrated circuit and a second state in which a current flows from the outside of the integrated circuit to the second output port.

2. The integrated circuit according to claim 1, wherein the magnetic field detection circuit comprises:
a magnetic field detection element configured to detect the external magnetic field and generate an electrical signal;
a signal processing unit configured to amplify and descramble the electrical signal; and
a conversion unit configured to convert the amplified and descrambled electrical signal into the magnetic field detection information, wherein an output terminal of the conversion unit is connected to the output control circuit and the first output port.

3. The integrated circuit according to claim 2, wherein the magnetic field detection information is a switch-type digital signal.

4. The integrated circuit according to claim 1, wherein the integrated circuit comprises at least four ports extending out from the housing.

5. The integrated circuit according to claim 4, wherein the integrated circuit comprises exactly four ports extending out from the housing.

6. The integrated circuit according to claim 1, wherein
the input ports comprise an input port configured to connect an external alternating current (AC) power supply, and
the output control circuit is configured to control, based on a polarity of the AC power supply and the magnetic field detection information, the integrated circuit to switch between at least the first state and the second state.

7. The integrated circuit according to claim 1, wherein
the output control circuit comprises a first switch and a second switch, wherein the first switch and the second output port are connected in a first current path, the second switch and the second output port are connected in a second current path having a direction opposite to that of the first current path, and the first switch and the second switch are turned on selectively based on the magnetic field detection information.

8. The integrated circuit according to claim 1, wherein
the output control circuit comprises a first current path in which a current flows out from the second output port, a second current path in which a current flows in from the second output port and a switch connected in one of the first current path and the second current path, wherein the switch is configured to control, based on the magnetic field detection information outputted from the magnetic field detection circuit, the first current path and the second current path to be turned on selectively.

9. The integrated circuit according to claim 6, wherein the output control circuit is configured to:
control a load current to flow through the second output port in a case that the AC power supply is in a positive half cycle and the external magnetic field is a first polarity or in a case that the AC power supply is in a negative half cycle and the external magnetic field is a second polarity opposite to the first polarity, and
control no load current to flow through the second output port in a case that the AC power supply is in a positive half cycle and the external magnetic field is the second polarity or in a case that the AC power supply is in a negative half cycle and the external magnetic field is the first polarity.

10. The integrated circuit according to claim 1, wherein
the input ports comprise a first input port and a second input port configured to connect an external AC power supply, and
the integrated circuit further comprises a rectifying circuit configured to convert an alternating current voltage outputted from the external power supply into a direct current voltage.

11. The integrated circuit according to claim 10, wherein the integrated circuit further comprises a voltage adjusting circuit configured to adjust a first voltage outputted from the rectifying circuit to a second voltage, wherein the first voltage is a supply voltage of the output control circuit, the second voltage is a supply voltage of the magnetic field detection circuit, and an average of the first voltage is greater than that of the second voltage.

12. A motor assembly, comprising:
a motor; and
a motor drive circuit comprising the magnetic sensor integrated circuit according to claim 1.

13. The motor assembly according to claim 12, wherein
the motor drive circuit further comprises a bidirectional switch connected in series with the motor across the external AC power supply, and
the second output port of the magnetic sensor integrated circuit is connected to a control terminal of the bidirectional switch.

14. The motor assembly according to claim 13, wherein
the motor comprises a stator and a permanent rotor, and
the stator comprises a stator core and a single-phase winding wound on the stator core.

15. The motor assembly according to claim 14, wherein the motor assembly further comprises a voltage dropper configured to reduce an output voltage of the AC power supply and provide the reduced voltage of the AC power supply to the magnetic sensor integrated circuit.

16. The motor assembly according to claim 14, wherein the magnetic sensor integrated circuit is configured to:
control the bidirectional switch to be turned on in a case the AC power supply is in a positive half cycle and a magnetic field of the permanent rotor is a first polarity or in a case that the AC power supply is in a negative half cycle and the magnetic field of the permanent rotor is a second polarity opposite to the first polarity, and
control the bidirectional switch to be turned off in a case that the AC power supply is in a negative half cycle and the magnetic field of the permanent rotor is the first polarity or in a case that the AC power supply is in a positive half cycle and the magnetic field of the permanent rotor is the second polarity.

17. The motor assembly according to claim 16, wherein the magnetic sensor integrated circuit is configured to:
control a current to flow from the integrated circuit to the bidirectional switch in a case that a signal outputted from the AC power supply is in a positive half cycle and the magnetic field of the permanent rotor is the first polarity, or
control a current to flow from the bidirectional switch to the integrated circuit in a case that the signal outputted from the AC power supply is in a negative half cycle and the magnetic field of the permanent rotor is the second polarity.

18. An application device comprising the motor assembly according to claim 12.

19. The application device according to claim 18, wherein the application device is a pump, a fan, a household appliance or a vehicle.
